(19) United States
(12) Patent Application Publication
(10) Pub. No.: US 2014/0204551 A1
(43) Pub. Date: Jul. 24, 2014

(54) CIRCUIT BOARD ASSEMBLY

(71) Applicant: Baumueller Nuernberg GmbH, Nuernberg (DE)

(72) Inventors: Rainer GRUNERT, Nuernberg (DE); Uwe HENSEL, Nuernberg (DE)

(73) Assignee: Baumueller Nuernberg GmbH, Nuernberg (DE)

(21) Appl. No.: 14/160,974

(22) Filed: Jan. 22, 2014

(30) Foreign Application Priority Data
Jan. 22, 2013 (DE) 10 2013 001 006.3

(51) Int. Cl. H05K 1/18

(52) U.S. Cl. CPC H05K 1/181
USPC 361/768

(57) ABSTRACT

A circuit board assembly with a printed circuit board, which has an SMD mounting location for attaching a first integrated circuit having an electrical circuit. A replacement circuit board having the electrical circuit is soldered at the SMD mounting location using SMD technology.

This nonprovisional application claims priority under 35 U.S.C. §119(a) to German Patent Application No. DE 10 2013 001 006.3, which was filed in Germany on Jan. 22, 2013, and which is herein incorporated by reference.

### BACKGROUND OF THE INVENTION

1. Field of the Invention

The present invention relates to a circuit board assembly with a printed circuit board populated using SMD (Surface Mount Device) technology. The circuit board assembly is in particular part of a control circuit of an electric motor.

2. Description of the Background Art

Electrical circuits are typically realized by means of printed circuit boards. These comprise electrical components, such as capacitors, resistors, and integrated circuits (IC), in which an electronic circuit arrangement is placed on a single semiconductor substrate. This results in cost savings and miniaturization in comparison with building the circuit assembly from individual discrete components. The electrical components are usually mounted on the circuit board by means of surface mounting (SMD technology), which enables both a miniaturization of the circuit board and weight and cost advantages. For this purpose, in a first work step solder paste is applied at certain locations of the circuit board. After this, the locations are populated with electrical components and in another work step the solder paste is heated to produce an electrical connection between the circuit board and the particular electrical component.

If certain integrated circuits, which are necessary for producing a circuit board, are no longer produced or at least no longer produced in the intended form, it is necessary to match the traces of the circuit board, which are provided for electrical contacting with the particular integrated circuit. This causes a complete change of the circuit board layout. The changed layout must be retested and checked for possible defects, which is relatively cost- and time-intensive, particularly if the circuit board is produced only in a relatively small quantity.

U.S. 2002/0093803 A1 discloses an adapter for an integrated circuit, which is available in an old and a new version as a surface-mounted device. In the old version, the circuit package has 68 pins and in the new version 44 pins. If the old version is not available, the new version is mounted on an adapter circuit board and the adapter circuit board on the circuit board that was provided for the old design of the integrated circuit. In this regard, the adapter circuit board lies on the circuit board and therefore is in direct mechanical contact with it.

DE 10 2006 053 461 A1 discloses a microelectronic subassembly with at least two parallel circuit carriers arranged one above the other. Two adjacent circuit carriers are mechanically connected by means of a surface-mounted device, whereby the surface-mounted device is part of a circuit of at least one of the circuit carriers.

### SUMMARY OF THE INVENTION

It is therefore an object of the present invention to provide a suitable circuit board assembly with a circuit board having an SMD mounting location for mounting a first integrated circuit that can be produced also if the first integrated circuit is not available, whereby the production expediently is to be relatively time- and cost-saving.

In an embodiment, the circuit board assembly comprises a circuit board which has an SMD mounting location. The SMD mounting location comprises a number of electrical contact points, which are oriented at a specific, predetermined distance and angle to one another. The contact points themselves are part of a trace, which is preferably in electrical contact with other electrical components of the circuit board, such as, e.g., capacitors or resistors. The arrangement of the contact points is such that a first integrated circuit can be contacted electrically with the SMD mounting location, whereby the mounting of the first integrated circuit on the circuit board occurs using SMD technology. The first integrated circuit has an electrical circuit. The electrical circuit during operation of the circuit board performs certain tasks, so that proper operation of the circuit board is made possible. The circuit board assembly in particular is part of a control circuit of an electric motor.

Instead of the first integrated circuit, a replacement circuit board is soldered to the SMD mounting location of the circuit board using SMD technology. The replacement circuit board is therefore a surface-mounted device. The BGA process (ball grid array) or a process similar to it is preferably used as the attachment method. Consequently, the replacement circuit board before mounting on the circuit board on the side facing the circuit board has a ball grid array, which is soldered to the contact points of the SMD mounting location during mounting.

The replacement circuit board has the electrical circuit of the first integrated circuit. In other words, the replacement circuit board takes on the functions of the first integrated circuit (IC), so that in the case of the mounted replacement circuit board no difference in the operation of the printed circuit board in comparison with the mounted first integrated circuit can be detected. For example, the electrical circuit is made at least partially of discrete devices, such as, e.g., resistors, capacitors, and the like.

It is possible by means of the replacement circuit board, on the one hand, to produce the properly functioning circuit board assembly, even if the first integrated circuit is no longer suppliable, available, or is defective or at least in the version suitable for the SMD mounting location. On the other hand, by means of the mounting of the replacement circuit board on the circuit board using SMD technology, there is a saving of time in comparison with other placement or mounting techniques. Thus, for example, it is made possible to assemble and to produce the circuit board only in one mounting process, provided the other possible electrical components of the circuit board can also be mounted by means of SMD technology.

In particular, other additional functions as well are realized by means of the replacement circuit board, so that the range of functions of the replacement circuit board is broadened in comparison with the first integrated circuit. The area of application of the circuit board assembly is expanded in this way and the functionality improved.

The replacement circuit board is contacted electrically via an electronic component with the SMD mounting location. The replacement circuit board thus is not in direct mechanical contact with the SMD mounting location. Rather, the electronic component is disposed between them. The electronic component is an SMD device, which is expediently attached in a surface-mounting process to the replacement circuit board. In particular, an electronic component is provided for each contact point of the SMD mounting location. In other words, the number the electronic components corresponds to the number of contact points of the SMD mounting location. A defined supporting surface of the replacement circuit board on the SMD mounting location is provided by using the electronic component, whereby based on the use of a surface- mounted device the production costs and the production time of the replacement circuit board are relatively low.

A capacitor is used as an electronic component. These are relatively simple and cost-effective to provide and procure. The two electrodes of the capacitor are short-circuited, therefore contacted electrically in a relatively low resistance manner, whereby in the mounting state particularly one of the two electrodes is electrically contacted with the replacement circuit board and the other electrode with the SMD mounting location. An influence of the capacitance of the capacitor on the electrical circuit of the replacement circuit board is ruled out in this way, whereby nevertheless a relatively simple attachment of the replacement board to the circuit board is made possible.

In an embodiment, the replacement circuit board can include a second integrated circuit, whose topology corresponds substantially to that of the first integrated circuit. In other words, the second integrated circuit has the electrical circuit. Production of the replacement circuit board in this way is relatively simple, because only the second integrated circuit needs to be mounted to create the electrical circuit. In this case, the replacement circuit board functions like an adapter, in order to upgrade a pin configuration of the second integrated circuit for mounting on the SMD mounting location. It is likewise possible that the topology of the second integrated circuit is made smaller in comparison with that of the first integrated circuit.

The second integrated circuit can be arranged suitably on the replacement circuit board side facing away from the circuit board and therefore also from the SMD mounting location and mounted there in particular. In other words, the replacement circuit board is located between the circuit board and the second integrated circuit. A visual check of the second integrated circuit is made possible in this way also in a completely mounted circuit board assembly. Further, a hot spot in the area of the second integrated circuit is avoided, which because of an insulation effect of the replacement circuit board is protected from possible heat generation on the circuit board.

Alternatively or in combination hereto, the second integrated circuit is a surface-mounted device. Consequently, the second integrated circuit itself is mounted using SMD technology on the replacement circuit board. This permits a relatively place-saving and cost-effective production of the replacement circuit board.

The second integrated circuit can have a package in an SO format (SO=small-outline). In particular, the package meets the requirements for a small-outline package and comprises a grid pitch of 1.27 mm. The second integrated circuit can have an SO format. Consequently, the dimensions of the second integrated circuit are relatively small, so that the space requirement on the replacement circuit board is relatively low. Advantageously, the dimension of the replacement circuit board corresponds substantially to that of the second integrated circuit or at least another SO format. By mounting the replacement circuit board on the printed circuit board using SMD technology, a relatively stable and defect-robust mounting is made possible, which is not the case with other mounting methods. Alternatively to the use of an SO format, the package has a TQFP, PLCC, or an otherwise standardized format. An alternative use of a grid pitch of 0.5 mm is also provided.

Advantageously, the replacement circuit board is made as one layer or especially preferably two-layered. In other words, the replacement circuit board is not a so-called multilayer board. In this way the replacement circuit board can be produced relatively cost-effectively and the construction cost is reduced.

For example, the electronic component has the form of a chip. The electronic component, for this reason, is substantially rectangular, which facilitates mounting, on the one hand, and simplifies storage, on the other. The types 01005, 0201, 0402, or 0603 are especially preferred; these have both a relatively wide distribution and especially suitable dimensions. Thus, for example, in the case of type 01005 the length of the electronic component is 0.4 mm and the width 0.2 mm and in the case of type 0603 the length is 1.60 mm and the width 0.80 mm.

The replacement circuit board can be spaced at least in sections from the circuit board and therefore has a physical distance from it. In particular, this gap is formed in a middle area of the replacement circuit board and is suitably provided between electronic components, provided an electrical connection is created by means of it between the replacement circuit board and the circuit board. In this regard, the gap preferably constitutes the dimension of the electronic component(s). In particular, an air gap is formed between the replacement circuit board and the circuit board.

Mounting is simplified, on the one hand, because of the gap. On the other hand, a thermal isolation of the replacement circuit board and its electrical circuit from the circuit board is realized. In addition, because of the gap an electrical short circuit between possible traces or non-isolated sections of the circuit board and the replacement circuit board is avoided. Expediently, the replacement circuit board is arranged substantially parallel to the circuit board, which results in a relatively small space requirement for the circuit board assembly.

The replacement circuit board can be made from a paper web or especially preferably from fiberglass cloth reinforced with epoxy resin. Preferably, the replacement circuit board is produced in the manner of a so-called stripboard. In other words, the replacement circuit board in the unmounted state has a grid, created by a number of holes, with a grid pitch of 1.2 mm. The holes are surrounded by an electrically conducting material, particularly by copper, particularly on the side facing the SMD mounting location, to form lands. The individual lands are advantageously electrically isolated from one another, to enable a plurality of different electrical circuits, without the fear of any short circuits or the like. Because of the use of a stripboard, the production time of the replacement circuit board is indeed increased. However, it is not necessary to use special tools for producing the replacement circuit boards or to program these accordingly. Only a standardized component is used and adjusted to the necessary size. Thus, a relatively simple and quick production of the replacement circuit board is made possible also in the case of a relatively small quantity.

The replacement circuit board has an electrical circuit and is set up and provided by means of SMD technology, particularly to be mounted on a circuit board using a BGA process or a BGA-like process (ball grid array). Expediently, the electrical circuit is realized in a second integrated circuit, which expediently has an SO8 format. On the side opposite to the second integrated circuit, the replacement circuit board comprises preferably an electronic component for contacting with an SMD mounting location of the circuit board.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows perspectively a circuit board with an SMD mounting location according to an exemplary embodiment;

FIG. 2 shows the circuit board with a first integrated circuit placed on the SMD mounting location;

FIG. 3 shows the circuit board with a replacement circuit board placed on the SMD mounting location;

FIG. 4 shows the replacement circuit board from above;

FIG. 5 shows the unpopulated (single-layer) replacement circuit board from below;

FIG. 6 shows the replacement circuit board populated with capacitors from below; and

FIGS. 7a-7d show a further embodiment of the replacement circuit board.

### DETAILED DESCRIPTION

In FIG. 1, a circuit board 2 with a number of capacitors and resistors 6 is shown perspectively, which are placed on a circuit board body 8 using SMD technology. Circuit board body 8 has fiberglass cloth impregnated with epoxy resin and comprises copper traces, which are not shown in greater detail and electrically contact electrical components 4, 6 with one another. Circuit board 2 comprises further an SMD mounting location 10 with eight contact points 12, which are made from the same material as the traces and are electrically contacted with them.

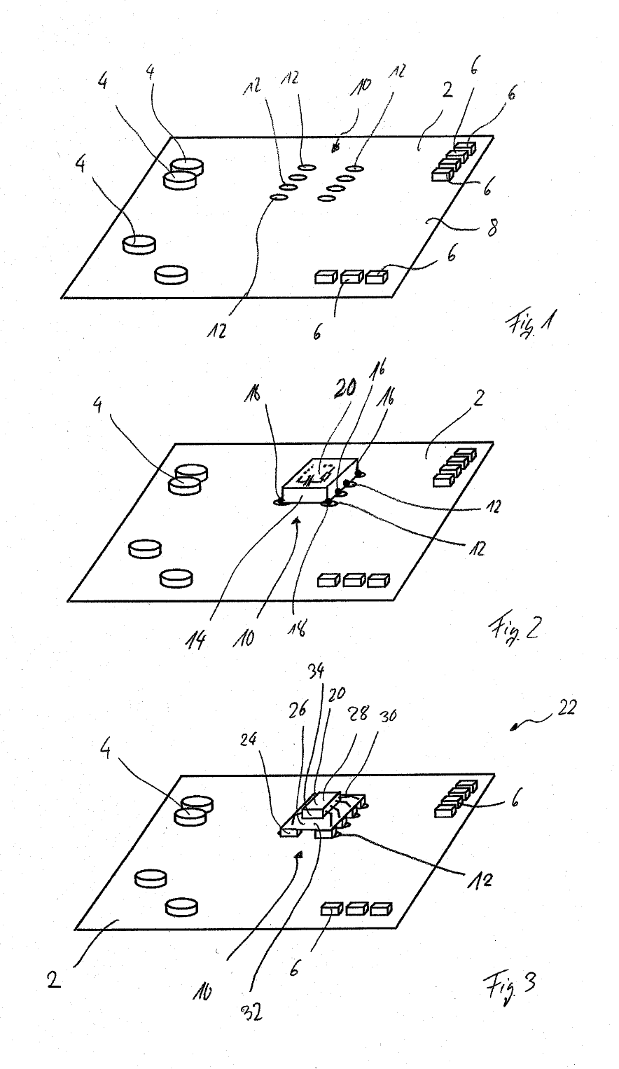

The fully assembled circuit board 2 is shown in FIG. 2, in which a first integrated circuit (IC) 14 is placed on the SMD mounting location 10. First integrated circuit 14 has a number of terminals 16 corresponding to the number of contact points 12; the terminals are electrically contacted using SMD technology via solder paste 18 with contact points 12 of SMD mounting location 10. First integrated circuit 14 has an electrical circuit 20, which is placed on an individual semiconductor substrate. First integrated circuit 14 by means of electrical circuit 20 looks after tasks that are necessary for operating an electric motor. Thus, control of flow control valves of an inverter of the electric motor is realized by means of first integrated circuit 14.

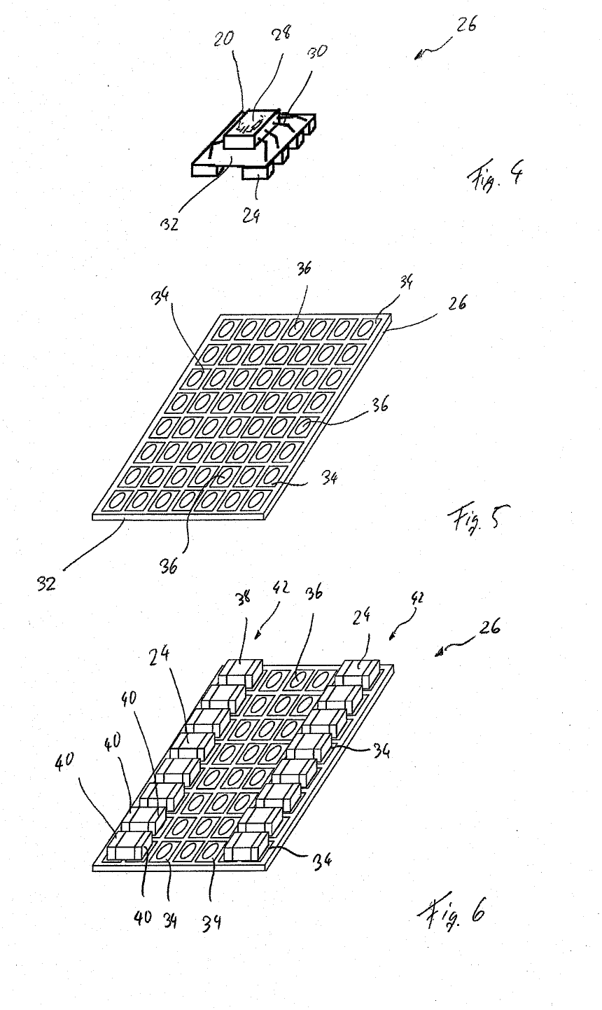

FIG. 3 shows a circuit board assembly 22 which fulfills the same tasks as circuit board 2 shown in FIG. 2. The circuit board assembly 22 is used, for example, if first integrated circuit 14 cannot be supplied. A replacement circuit board 26, shown in greater detail in FIG. 4, is electrically contacted with SMD mounting location 10 in this case via a number of electronic components 24, the number corresponding to the number of contact points 12. In so doing, both the electronic components 24 on replacement circuit board 26 as well as replacement circuit board 26 are placed via electronic components 24 on SMD mounting location 10 using SMD technology. As a result, it is made possible to solder replacement circuit board 26 in one work step with capacitors 4 and resistors 6 to circuit board body 8.

Replacement circuit board 26 is kept hereby at a distance to circuit board 2 by means of electronic components 24, which are arranged on the side, facing circuit board 2, of replacement circuit board 26, whereby the support points of replacement circuit board 26 on circuit board 2 are determined by means of electronic components 24. In this regard, replacement circuit board 26 is oriented substantially parallel to circuit board 2. A second integrated circuit 28 with terminals 30 is placed on the side, facing away from circuit board 2, of replacement circuit board 26, whereby terminals 30 can be through-contacted by a replacement circuit board body 32 with electronic components 24. In other words, in each case one of the terminals 30 is electrically connected via an assigned electronic component 24 with one of the contact points 12 of SMD mounting location 10. Terminals 30 determine hereby the form of second integrated circuit 28 and are part of a package 24, which is produced according to the SO8 format. Second integrated circuit 28 further has the same electrical circuit 20 as first integrated circuit 14 according to FIG. 2. Only the connection configuration, therefore the arrangement of terminals 16, 30 is different in the two integrated circuits 14, 28. Thus, circuit board assembly 22 shown in FIG. 3 is also part of a control circuit of an electric motor.

The side, facing circuit board 2, of the unpopulated replacement circuit board body 32 is shown perspectively in FIG. 5. Replacement circuit board body 32 is a stripboard, produced from fiberglass cloth impregnated with epoxy resin, with a number of lands 34, which are isolated from one another and in each case have a central hole 36. Holes 36 are arranged in a grid with a grid pitch of 1.27 mm. Lands 34 comprise an electrically conductive material such as, for example, copper.

Replacement circuit board 26, populated with electronic components 24, according to FIG. 5 is shown in FIG. 6, whereby the number of electronic components 24 corresponds to twice the number of electronic components 24 of replacement circuit board 26 shown in FIG. 3 and FIG. 4. Electronic components 24 in each case are a capacitor 38, which has a chip form. The form is the same as 0603. Consequently, each capacitor 28 has two circumferential electrodes 40. The two electrodes 40 of each capacitor 38 are electrically contacted with one of lands 34, whereby lands 34 are adjacent to one another. In this case, surface-mounted capacitors 38 are arranged in two rows 42, which overlap the lands 34 located on opposite edges of replacement circuit board body 32. In this case, in the assembled state the outermost lands 34, located closest to the edge, are electrically contacted via assigned electrode 40 with the respective contact points 12 of SMD mounting location 10 and soldered there. Second integrated circuit 28 is electrically contacted via terminals 30 through specific hole 36. For this purpose, the specific holes 36 are filled with solder paste for through-contacting.

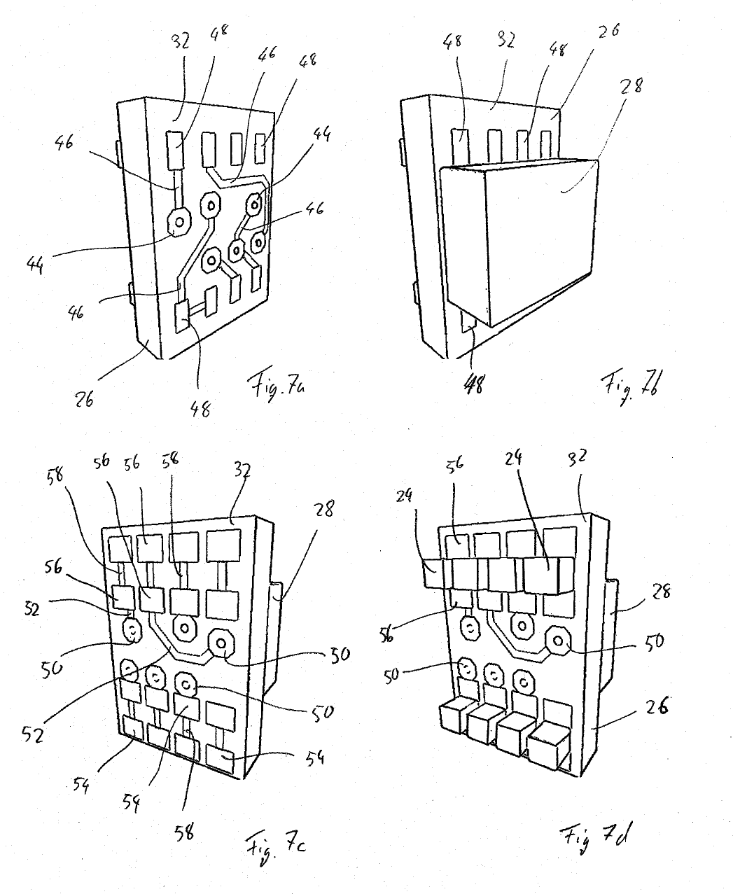

A further embodiment of replacement circuit board 26 with a modified replacement circuit board body 32 is shown perspectively in FIG. 7a. Replacement circuit board body 32, produced in an etching or printing process, has six first lands 44, which are electrically connected via first traces 46 and/or mounting surfaces 48. In the assembled state, as shown in FIG. 7b, second integrated circuit 28 is attached to first mounting surface 48 in an electrically conducting manner by means of SMD technology.

Each first land 44 is electrically contacted with an assigned second land 50, whereby second lands 50 are located on the side, opposite to second integrated circuit 28, of replacement circuit board body 32. In other words, the first and second lands 44, 50 are through-contacted and replacement circuit board body 32 is made as two layers.

Second lands 50 themselves are further electrically contacted either directly or by means of second traces 52 with second mounting surfaces 54 on the same replacement circuit board body side. Each second mounting surface 54 has two contact surfaces 56 spaced apart from one another, which are made from the material of traces 46, 52 and are connected together via a bar 58 made of the same material. Electronic component 24 is mounted on each mounting surface 54, whereby electronic component 24 is soldered using SMD technology to each of the contact surfaces 56 of the assigned mounting surface 54, as shown in FIG. 7d. Electronic components 24 are therefore connected electrically parallel to the assigned relatively low-resistance bar 58. In this way the effect of the electrical properties of electronic components 24 on the operating mode of replacement circuit board 26 is negligible. Because of the use of lands 44, 50 and the assigned traces 46, 52, it is made possible to use a second integrated circuit 28, whose terminal configuration differs from that of first integrated circuit 14.

The invention is not limited to the exemplary embodiments described above. Rather, other variants of the invention can also be derived herefrom by the person skilled in the art, without going beyond the subject matter of the invention. Particularly, all individual features described in relation to the individual exemplary embodiments can also be combined with one another in a different manner, without going beyond the subject matter of the invention.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A circuit board assembly with a printed circuit board, which has an SMD mounting location for attaching a first integrated circuit having an electrical circuit, whereby a replacement circuit board having the electrical circuit is soldered at the SMD mounting location using SMD technology, the replacement circuit board being electrically contacted via an electronic component with the SMD mounting location, the electronic component being a surface-mounted device, the electronic component being a capacitor, and the electrodes of the capacitor being short-circuited.

2. The circuit board assembly according to claim 1, wherein the replacement circuit board comprises a second integrated circuit having the electrical circuit.

3. The circuit board assembly according to claim 2, wherein the second integrated circuit is arranged on a side facing away from the circuit board of the replacement circuit board.

4. The circuit board assembly according to claim 2, wherein the second integrated circuit is a surface-mounted element.

5. The circuit board assembly according to claim 2, wherein the second integrated circuit has a package in an SO format or an SO8 format.

6. The circuit board assembly according to claim 5, wherein the electronic component is a chip, particularly 0603, 0402, 0201, or 01005.

7. The circuit board assembly according to claim 1, wherein the replacement circuit board is spaced apart at least in sections from the circuit board or the replacement circuit board is parallel to the circuit board.

8. The circuit board assembly according to claim 1, wherein the replacement circuit board comprises a stripboard with a number of lands, which are electrically isolated from one another.
